(19) United States
(12) Patent Application Publication
(10) Pub. No.: US 2023/0140727 A1
(43) Pub. Date: May 4, 2023

(54) METHOD AND ELECTRONIC DEVICE FOR EVALUATING REMAINING USEFUL LIFE (RUL) OF BATTERY

(71) Applicant: SAMSUNG ELECTRONICS CO., LTD., Suwon-si (KR)

(72) Inventors: Subramanian Brahmadathan Swernath, Bengalru (IN); Krishnan Seethalakshmy Hariharan, Bengalru (IN); Samarth Agarwal, Bengalru (IN); Seongho Han, Suwon-si (KR)

(73) Assignee: SAMSUNG ELECTRONICS CO., LTD., Suwon-si (KR)

(21) Appl. No.: 17/968,348

(22) Filed: Oct. 18, 2022

Related U.S. Application Data
(63) Continuation of application No. PCT/KR2022/011734, filed on Aug. 8, 2022.

(30) Foreign Application Priority Data
Nov. 4, 2021 (IN) 202141050701

(51) Int. Cl. G01R 31/392; G01R 31/367; G01R 31/385; G01R 31/396

(52) U.S. Cl. CPC G01R 31/392; G01R 31/367; G01R 31/385; G01R 31/396

(57) ABSTRACT

An electronic device, including a memory; a processor; and a remaining useful life (RUL) prediction controller configured to: identify at least one parameter corresponding to at least one of a physical composition and a chemical composition of a plurality of used batteries during at least one of a charging and a discharging of the plurality of used batteries; determine a pattern of variations in at least one of a voltage, a current, a temperature, and a resistance during every cycle of the charging and the discharging of the plurality of used batteries until a failure; generate an artificial intelligence (AI) model which is trained based on a correlation between the determined pattern of variations and the at least one of the physical composition and the chemical composition; and evaluate a RUL of the plurality of used batteries using the AI model.

### CROSS-REFERENCE TO RELATED APPLICATION(S)

This application is a bypass continuation of International Application No. PCT/KR2022/011734, filed on Aug. 8, 2022 in the Korean Intellectual Property Office and Indian Application No. 202141050701, filed on Nov. 4, 2021 in the Indian Intellectual Property Office, the disclosures of which are incorporated by reference herein in their entireties.

### BACKGROUND

### 1. Field

The present disclosure relates to the field of a battery management system, and more particularly to a method and an electronic device for evaluating a Remaining Useful Life (RUL) of a battery.

### 2. Description of the Related Art

Various methods may be used for predicting instead of evaluating a Remaining Useful Life (RUL) of a battery using a large amount of data. These methods may provide a prediction the RUL of the battery at an advanced stage of the battery which is too late for any prudent corrective action. Further, this predication may rely on specialized battery features, which may result in inconveniencing a user of the battery.

Thus, there is a need to address the above mentioned disadvantages or other shortcomings or provide a useful alternative.

### SUMMARY

Provided are a method and an electronic device for evaluating a RUL of a battery.

Also provided is a method of using a data driven model (e.g., AI model and/or battery model) to predict when a battery will fail with very minimal number of battery cycles.

Also provided is a data driven model, for example an artificial intelligence (AI) model and/or a battery model that is trained based on correlation between variations in voltage, current, and resistance and future battery failure causes. The AI model or the battery model may be used for detecting early indicators of such failures of the battery. The AI model or the battery model may identify sudden death from very few initial cycles even without having seen sudden death data. The AI model or the battery model may be the only prediction technique possible with very few initial cycles, for example very few examples of charging/discharging data. The AI model or the battery model may identify early signs of non-linear degradation that may cause battery sudden death (in addition to linear degradation) in very few initial cycles to predict battery sudden death in the far future.

Also provided is a method of evaluating the RUL of the battery with a minimal data and in an efficient and fast manner. By using minimal initial data, the method may be used to provide an improved battery design.

Additional aspects will be set forth in part in the description which follows and, in part, will be apparent from the description, or may be learned by practice of the presented embodiments.

In accordance with an aspect of the disclosure, an electronic device includes a memory; a processor; and a remaining useful life (RUL) prediction controller, coupled with the memory and the processor, and configured to: identify at least one parameter corresponding to at least one of a physical composition and a chemical composition of a first plurality of used batteries during at least one of a charging of the first plurality of used batteries and a discharging of the first plurality of used batteries; determine a pattern of variations in at least one of a voltage, a current, a temperature, and a resistance during every cycle of the charging of the first plurality of used batteries and every cycle of the discharging of the first plurality of used batteries until an occurrence of a failure for the first plurality of used batteries; generate an artificial intelligence (AI) model which is trained based on a correlation between the determined pattern of variations and the at least one of the physical composition of the first plurality of used batteries and the chemical composition of the first plurality of used batteries; and evaluate a RUL of the first plurality of used batteries using the AI model.

The RUL prediction controller may be further configured to: store the generated AI model in the memory.

The RUL prediction controller may be further configured to: identify at least one of a physical composition of a candidate battery and a chemical composition of the candidate battery, and identify a candidate pattern of variations in at least one of a voltage, a current, a temperature, and a resistance during every cycle of a charging of the candidate battery and a discharging of the candidate battery; provide the at least one of the physical composition of the candidate battery and the chemical composition of the candidate battery, and the identified candidate pattern of variations to the AI model; and predict an occurrence of failure of the candidate battery using the AI model.

To perform the predicting, the at RUL prediction controller may be further configured to: provide at least one of the physical composition of the candidate battery and the chemical composition of the candidate battery, and the identified candidate pattern of variations with the AI model which is trained based on the correlation of the determined pattern of variations and the at least one of the physical composition and the chemical composition of the first plurality of used batteries; and predict the occurrence of failure of the candidate battery based on a result obtained from the AI model.

The predicting of the occurrence of failure of the candidate battery may include at least one of determining the RUL of the candidate battery and predicting a cycle number at which a sudden death of the candidate battery will occur.

The AI model may be configured to: determine the RUL of the first plurality of used batteries based on one or more initial cycles without receiving sudden death data of the first plurality of used batteries, by identifying signs of a non-linear degradation corresponding to battery sudden death in addition to linear degradation in the one or more initial cycles to predict the battery sudden death in at a future time.

The at least one of the physical composition and the chemical composition of the first plurality of used batteries may include a resistance growth, a porosity decay rate, a pre-exponential constant defining a Lithium Plating (LiP) current flux, a capacity drop, and a pre-exponential constant defining a solid electrolyte interface current flux.

The RUL prediction controller may be further configured to track the pattern of variations in the at least one of the voltage, the current and the resistance during at least one of a charging of each of the first plurality of used batteries and a discharging of each of the first plurality of used batteries.

The RUL prediction controller may be further configured to predict an occurrence of failure of a candidate battery used in at least one of an electric vehicle (EV) and a hybrid vehicle based on the AI model.

In accordance with an aspect of the disclosure, an electronic device includes a memory; a processor; and a remaining useful life (RUL) prediction controller, coupled with the memory and the processor, and configured to: determine a charging of a battery and a discharging of the battery for a predetermined number of cycles; measure at least one of voltage, current, a temperature, and a resistance of the battery during the charging of the battery and the discharging of the battery; provide the at least one of the voltage, the current, the temperature, and the resistance to at least one of a battery model and an Artificial intelligence (AI) model; and obtain at least one of a physical indicator and a chemical indicator representing a remaining useful life (RUL) of the battery using the at least one of the battery model and the AI model.

The RUL prediction controller may be further configured to train the at least one of the AI model and the battery model to estimate battery parameters based on a pattern of measured voltage, current, and resistance indicative of an occurrence of failure.

The at least one of the AI model and the battery model may include a correlation a measured pattern of variations and identified physical indicators and chemical indicators corresponding to the RUL of the battery.

The RUL prediction controller may be further configured to track a pattern of variations in the at least one of the voltage, the current, the temperature, and the resistance during at least one of the charging of the battery and the discharging of the battery.

In accordance with an aspect of the disclosure, a method for evaluating a remaining useful life (RUL) of a battery includes identifying, by an electronic device, at least one parameter corresponding to at least one of a physical composition and a chemical composition of a first plurality of used batteries during at least one of a charging of the first plurality of used batteries and a discharging of the first plurality of used batteries; determining, by the electronic device, a pattern of variations in at least one of a voltage, a current, a temperature, and a resistance during every cycle of charging of the first plurality of used batteries and every cycle of the discharging of the first plurality of used batteries until an occurrence of failure for the first plurality of used batteries; generating, by the electronic device, an artificial intelligence (AI) model which is trained based on a correlation of the determined pattern of variations and the at least one of the physical composition of the first plurality of used batteries and the chemical composition of the first plurality of used batteries; and evaluating, by the electronic device, a RUL of the first plurality of used batteries using the AI model.

The method may further include storing, by the electronic device, the generated AI model in a memory.

In accordance with an aspect of the disclosure, an electronic device includes a memory; and at least one processor configured to: determine at least one physical parameter corresponding to at least one of a physical composition of a battery and a chemical composition of the battery during a predetermined number of cycles corresponding to at least one of a charging and a discharging of the battery; determine a pattern of variations in at least one of a voltage, a current, a temperature, and a resistance of the battery during the predetermined number of cycles; train an artificial intelligence (AI) model which based on a correlation between the determined pattern of variations and the at least one physical parameter; and evaluate a remaining useful life (RUL) of the battery based on the AI model.

The at least one processor may be further configured to: determine a pattern of additional variations in the at least one of the voltage, the current, the temperature, and the resistance of the battery during at least one cycle after the predetermined number of cycles; provide the pattern of additional variations to the AI model; and evaluate an updated RUL of the battery based on the AI model.

### BRIEF DESCRIPTION OF THE DRAWINGS

The above and other aspects, features, and advantages of certain embodiments of the present disclosure will be more apparent from the following description taken in conjunction with the accompanying drawings, in which:

FIG. 1 shows various hardware components of an electronic device, according to an embodiment;

FIG. 2a, FIG. 2b and FIG. 3 are flow charts illustrating a method for evaluating a RUL of a battery, according to embodiments;

FIG. 4a to FIG. 4c are example illustrations in which battery failure detection is depicted using a training stage of an AI model and a testing stage of the AI model, according to embodiments;

FIG. 4d is an example illustration in which battery failure detection is depicted using various graphs, according to an embodiment;

FIG. 5 is an example illustration in which comparison of battery ageing between experiments and modeling for three different C-rates using the AI model is depicted, according to an embodiment; and

FIG. 6a and FIG. 6b are example illustrations in which early indicators of battery failure is depicted, according to an embodiment.

### DETAILED DESCRIPTION

The example embodiments herein and the various features and advantageous details thereof are explained more fully with reference to the non-limiting embodiments that are illustrated in the accompanying drawings and detailed in the following description. Descriptions of well-known components and processing techniques are omitted so as to not unnecessarily obscure the embodiments herein. The description herein is intended merely to facilitate an understanding of ways in which the example embodiments herein can be practiced and to further enable those of skill in the art to practice the example embodiments herein. Accordingly, this disclosure should not be construed as limiting the scope of the example embodiments herein.

Accordingly, the embodiments herein disclose a method for evaluating a Remaining Useful Life (RUL) of a battery. Embodiments relate to identifying, by an electronic device, at least one parameter corresponding to at least one of a physical composition and a chemical composition of a first plurality of used batteries during at least one of a charging of the first plurality of used batteries and a discharging of the first plurality of used batteries. Further, embodiments relate to determining, by the electronic device, a pattern of variations in at least one of a voltage, a current, a temperature and a resistance during every cycle of charging of the first plurality of used batteries and every cycle of the discharging of the first plurality of used batteries until an occurrence of failure for the first plurality of used batteries. Further, embodiments relate to generating, by the electronic device, an artificial intelligence (AI) model which is trained based on a correlation of the determined pattern of variations and the at least one of the identified physical composition of the first plurality of used batteries and the chemical composition of the first plurality of used batteries. Further, embodiments relate to evaluating, by the electronic device, the RUL of the first plurality of used batteries using the AI model.

Unlike some other methods and systems, the AI model and/or battery model may be trained with correlation between variations in the voltage, the current, and the resistance and future battery failure causes. The AI model or the battery model may be used for detecting early indicators of such failures of the battery. The AI model or the battery model identifies sudden death from very few initial cycles even without having seen sudden death data. The AI model or the battery model may be the only prediction technique possible with very few initial cycles, for example very few examples of charging/discharging data. The AI model or the battery model may identify early signs of non-linear degradation that causes battery sudden death (in addition to linear degradation) in very few initial cycles to predict battery sudden death in the far future.

Embodiments may be used to predict remaining useful life at any stage or cycle of the battery with a minimal time, low cost and efficient and fast manner. By using minimal initial data, the method can be used to provide the best battery design.

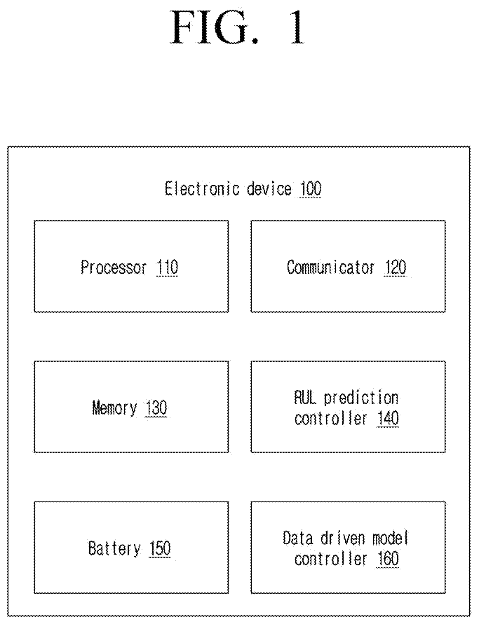

Referring now to the drawings, and more particularly to FIGS. 1 through 6b, where similar reference characters denote corresponding features consistently throughout the figures, there are shown example embodiments.

FIG. 1 shows various hardware components of an electronic device (100), according to embodiments as disclosed herein. The electronic device (100) can be, for example, but not limited to a smart phone, a laptop, a vehicle to everything (V2X) device, a tablet, an immersive device, a virtual reality device, a foldable device and an Internet of things (IoT) device. In an embodiment, the electronic device (100) may include a processor (110), a communicator (120), a memory (130), a RUL prediction controller (140), a battery (150) and a data driven model controller (160). The processor (110) may be coupled with the communicator (120), the memory (130), the RUL prediction controller (140), the battery (150) and the data driven model controller (160). The battery (150) may be, for example, a lithium ion battery, a nickel cadmium battery, a magnesium-ion battery, a nickel metal hydride battery, and a relatively small sealed lead acid battery, however embodiments are not limited thereto.

The RUL prediction controller (140) may be configured to identify a parameter corresponding to a physical composition and a chemical composition of a first plurality of used batteries during a charging of the first plurality of used batteries and a discharging of the first plurality of used batteries. The identified physical composition and the chemical composition may be, for example, a resistance growth, a porosity decay rate, a pre-exponential constant defining the Lithium Plating (LiP) current flux, a capacity drop, and a pre-exponential constant that defines the solid electrolyte interface current flux, however embodiments are not limited thereto.

Further, the RUL prediction controller (140) may be configured to determine a pattern of variations in a voltage, a current, a temperature and a resistance during every cycle of charging of the first plurality of used batteries and every cycle of the discharging of the first plurality of used batteries until an occurrence of failure for the first plurality of used batteries. After determination, the RUL prediction controller (140) may be configured to generate a data driven model (e.g., AI model or the like) comprising the correlation of the determined pattern of variations and the identified physical composition of the first plurality of used batteries and the chemical composition of the first plurality of used batteries using the data driven model controller (160). Based on the AI model, the RUL prediction controller (140) may be configured to evaluate the RUL of the first plurality of used batteries.

Further, the RUL prediction controller (140) may be configured to store the generated AI model including the correlation of the determined pattern of variations and the identified physical composition of the first plurality of used batteries and the chemical composition of the first plurality of used batteries.

Further, the RUL prediction controller (140) may be configured to identify a physical composition of the candidate battery (150) and a chemical composition of the candidate battery (150), and a pattern of variations in the voltage, the current, the temperature and the resistance during every cycle of charging of the candidate battery (150) and a discharging of the candidate battery (150). After the identification, the RUL prediction controller (140) may be configured to provide the identified physical composition of the candidate battery (150) and the identified chemical composition of the candidate battery (150), and the identified pattern of variations in the voltage, the current, the temperature and the resistance during every cycle of charging of the candidate battery (150) and the discharging of the candidate battery (150) to the AI model, for example by sharing with the AI model.

After these are provided to the AI model, the RUL prediction controller (140) may be configured to compare the identified physical composition of the candidate battery (150) and the identified chemical composition of the candidate battery (150), and the identified pattern of variations in the voltage, the current, the temperature and the resistance during every cycle of charging of the candidate battery (150) and the discharging of the candidate battery (150) with the AI model including the correlation of the determined pattern of variations and the identified physical composition and the chemical composition of the first plurality of used batteries. Based on the comparison, the RUL prediction controller (140) may be configured to predict the occurrence of failure of the candidate battery (150). The occurrence of failure of the candidate battery (150) corresponds to the identify the RUL of the candidate battery (150) at any time and predict the cycle number at which sudden death of the candidate battery (150) occurs.

Further, the AI model may identify the RUL of the battery (150) from very initial cycles even without having seen sudden death data of the first plurality of used batteries. Further, the AI model may identify early signs of a non-linear degradation that causes battery sudden death in addition to linear degradation in very few initial cycles to predict battery sudden death in a future.

In an embodiment, the RUL prediction controller (140) may be configured to determine the charging of the battery (150) and the discharging of the battery (150) for the predetermined number of cycles. During the charging of the battery (150) and the discharging of the battery (150), the RUL prediction controller (140) may be configured to measure at the voltage, the current, the temperature and resistance of the battery (150). Further, the RUL prediction controller (140) may be configured to provide the voltage, the current, the temperature and resistance measured during the charging of the battery (150) and the discharging of the battery (150) to the battery model and the AI model. The AI model and the battery model may include the correlation of the measured pattern of variations and identified physical and chemical indicators representative of the RUL of the battery (150). Using the battery model and the AI model, the RUL prediction controller (140) is configured to obtain the physical indicator and the chemical indicator representative of RUL of the battery (150). Further, the RUL prediction controller (140) may be configured to train the AI model and the battery model for estimation of battery parameters with the pattern of measured voltage, the current, and the resistance indicative of the occurrence of failure.

The RUL prediction controller (140) may be physically implemented by analog or digital circuits such as logic gates, integrated circuits, microprocessors, microcontrollers, memory circuits, passive electronic components, active electronic components, optical components, hardwired circuits, or the like, and may optionally be driven by firmware.

Further, the processor (110) may be configured to execute instructions stored in the memory (130) and to perform various processes. The communicator (120) may be configured for communicating internally between internal hardware components and with external devices via one or more networks. The memory (130) may store instructions to be executed by the processor (110). The memory (130) may include non-volatile storage elements. Examples of such non-volatile storage elements may include magnetic hard discs, optical discs, floppy discs, flash memories, or forms of electrically programmable memories (EPROM) or electrically erasable and programmable (EEPROM) memories. In addition, the memory (130) may, in some examples, be considered a non-transitory storage medium. The term “non-transitory” may indicate that the storage medium is not embodied in a carrier wave or a propagated signal. However, the term “non-transitory” should not be interpreted that the memory (130) is non-movable. In certain examples, a non-transitory storage medium may store data that can, over time, change (e.g., in Random Access Memory (RAM) or cache).

Further, at least one of the plurality of modules/controller may be implemented through the AI model using the data driven model controller (160). A function associated with the AI model may be performed through the non-volatile memory, the volatile memory, and the processor (110). The processor (110) may include one or a plurality of processors. In embodiments, one or a plurality of processors may be a general purpose processor, such as a central processing unit (CPU), an application processor (AP), or the like, a graphics-only processing unit such as a graphics processing unit (GPU), a visual processing unit (VPU), and/or an AI-dedicated processor such as a neural processing unit (NPU).

The one or a plurality of processors may control the processing of the input data in accordance with a predetermined operating rule or AI model stored in the non-volatile memory and the volatile memory. The predetermined operating rule or artificial intelligence model may be provided through training or learning.

Here, being provided through learning may mean that a predetermined operating rule or AI model of a desired characteristic is made by applying a learning algorithm to a plurality of learning data. The learning may be performed in a device itself in which AI according to an embodiment is performed, and/or may be implemented through a separate server or system.

The AI model may include a plurality of neural network layers. Each layer may have a plurality of weight values, and may perform a layer operation through calculation of a previous layer and an operation of a plurality of weights. Examples of neural networks may include, but are not limited to, convolutional neural network (CNN), deep neural network (DNN), recurrent neural network (RNN), restricted Boltzmann Machine (RBM), deep belief network (DBN), bidirectional recurrent deep neural network (BRDNN), generative adversarial networks (GAN), and deep Q-networks.

The learning algorithm may be a method for training a predetermined target device (for example, a robot) using a plurality of learning data to cause, allow, or control the target device to make a determination or prediction. Examples of learning algorithms include, but are not limited to, supervised learning, unsupervised learning, semi-supervised learning, or reinforcement learning.

Although FIG. 1 shows various hardware components of the electronic device (100), embodiments are not limited thereto. In embodiments, the electronic device (100) may include less or more number of components. Further, the labels or names of the components are used only for illustrative purpose and do not limit the scope of the disclosure. One or more components may be combined together to perform same or substantially similar function in the electronic device (100).

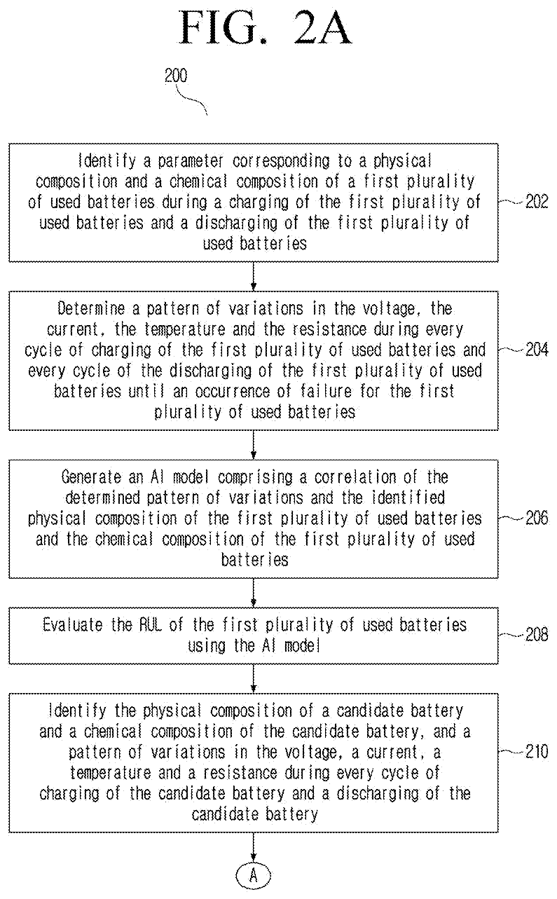

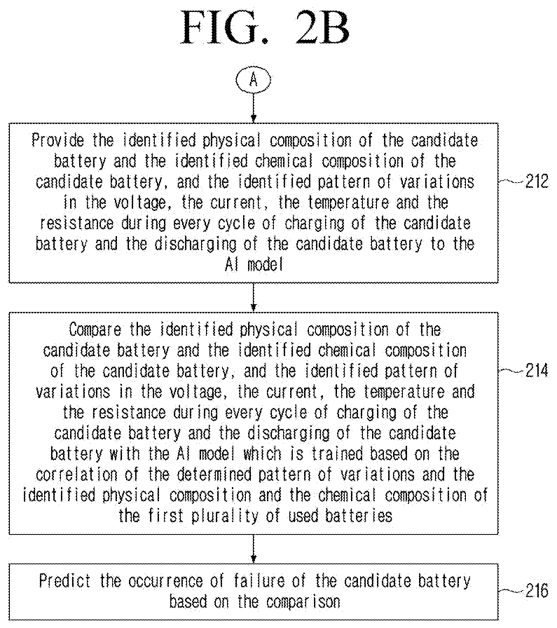

FIG. 2A, FIG. 2B and FIG. 3 are flow charts illustrating a process 200 and a process 300 for evaluating the RUL of the battery (150), according to embodiments as disclosed herein. In embodiments, the operations illustrated in FIGS. 2A-2B may be performed by one or more of the elements illustrated in FIG. 1, for example the RUL prediction controller (140).

As shown in FIG. 2A, at operation 202, process 200 may include identifying the parameter corresponding to the physical composition and the chemical composition of the first plurality of used batteries during the charging of the first plurality of used batteries and the discharging of the first plurality of used batteries. At operation 204, process 200 may include determining the pattern of variations in the voltage, the current, the temperature and the resistance during every cycle of charging of the first plurality of used batteries and every cycle of the discharging of the first plurality of used batteries until the occurrence of failure for the first plurality of used batteries.

At operation 206, process 200 may include generating the AI model including the correlation of the determined pattern of variations and the identified physical composition of the first plurality of used batteries and the chemical composition of the first plurality of used batteries. At operation 208, process 200 may include evaluating the RUL of the first plurality of used batteries using the AI model.

At operation 210, process 200 may include identifying the physical composition of the candidate battery (150) and the chemical composition of the candidate battery (150), and the pattern of variations in the voltage, the current, the temperature and the resistance during every cycle of charging of the candidate battery (150) and the discharging of the candidate battery (150). As shown in FIG. 2A, at operation 212, process 200 may include providing the identified physical composition of the candidate battery (150) and the identified chemical composition of the candidate battery (150), and the identified pattern of variations in the voltage, the current, the temperature and the resistance during every cycle of charging of the candidate battery (150) and the discharging of the candidate battery (150) to the AI model.

At operation 214, process 200 may include comparing the identified physical composition of the candidate battery (150) and the identified chemical composition of the candidate battery (150), and the identified pattern of variations in the voltage, the current, the temperature and the resistance during every cycle of charging of the candidate battery (150) and the discharging of the candidate battery (150) with the AI model including the correlation of the determined pattern of variations and the identified physical composition and the chemical composition of the first plurality of used batteries. In embodiments, the comparing may include evaluating at least one of the identified physical composition of the candidate battery (150) and the identified chemical composition of the candidate battery (150), and the identified pattern of variations in the voltage, the current, the temperature and the resistance during every cycle of charging of the candidate battery (150) and the discharging of the candidate battery (150) using the AI model, which may be trained based on the correlation of the determined pattern of variations and the identified physical composition and the chemical composition of the first plurality of used batteries, and receiving an output result of the AI model which may be the comparison result. At operation 216, process 200 may include predicting the occurrence of failure of the candidate battery (150) based on the comparison.

As shown in FIG. 3, at operation 302, process 300 may include determining the charging of the battery (150) and the discharging of the battery (150) for the predetermined number of cycles. At operation 304, process 300 may include measuring the voltage, the current, the temperature and the resistance of the battery (150) during the charging of the battery (150) and the discharging of the battery (150). At operation 306, process 300 may include providing the voltage, the current, the temperature and resistance measured during the charging of the battery (150) and the discharging of the battery (150) to the battery model and the AI model. At operation 308, process 300 may include obtaining the physical indicator and the chemical indicator representative of RUL of the battery (150) using the battery model and the AI model.

In embodiments, the AI model and/or battery model may be trained based on correlation between variations in the voltage, the current, and the resistance and future battery failure causes. The AI model or the battery model may be used for detecting early indicators of such failures of the battery. The AI model or the battery model may identify sudden death from very few initial cycles even without having seen sudden death data. The AI model or the battery model may be the only prediction technique possible with very few initial cycles, for example very few examples of charging/discharging data. The AI model or the battery model may identify early signs of non-linear degradation that causes battery sudden death (in addition to linear degradation) in very few initial cycles itself to predict battery sudden death in the far future. The method can be used to predict remaining useful life at any stage or cycle of the battery with a minimal time, low cost and efficient and fast manner. By using minimal initial data, the method can be used to provide the best battery design. The proposed method is not only used in the electronic device (100), but also used in an electric vehicle (EV) and a hybrid vehicle including the battery (150).

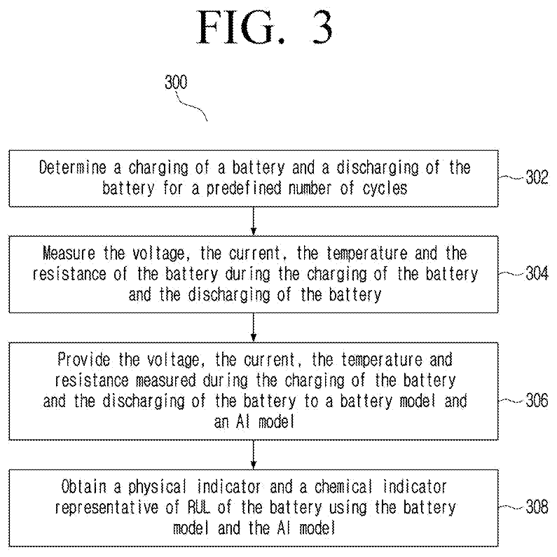

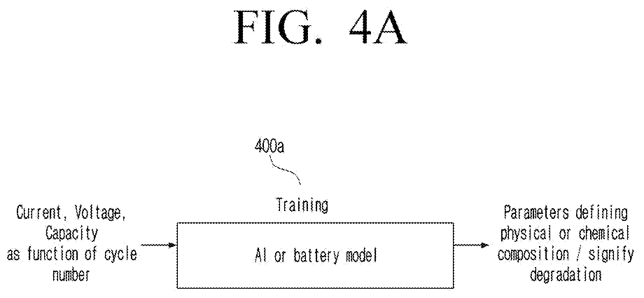

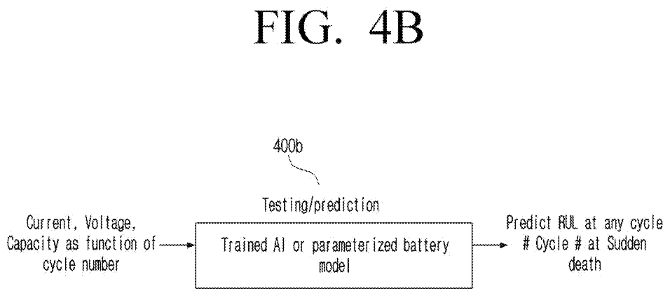

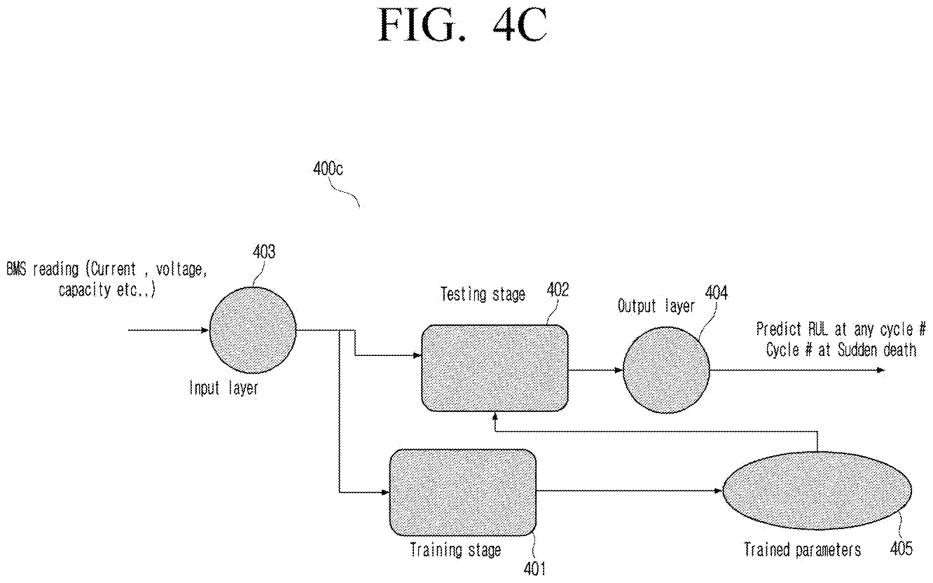

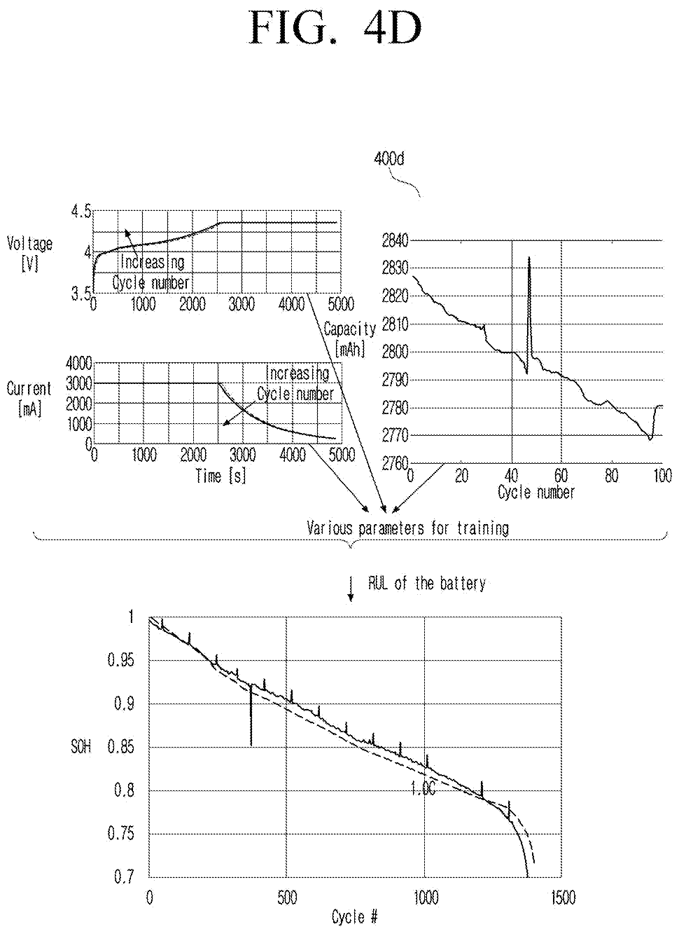

FIG. 4A to FIG. 4C are example illustrations in which battery failure detection is depicted using a training stage of the AI model and a testing stage of the AI model, according to embodiments as disclosed herein.

As shown in FIG. 4A, for the training stage (400a), the AI model or the battery model may be trained based on a correlation or correlations between variations in the voltage, the current, the capacity as a function of cycle number and the resistance and future battery failure causes. The training stage provides an output, for example parameters defining the physical or chemical composition, or which signify degradation of the battery (150). Example training steps A1-A5 are provided below:

A1: Initial 100 cycles of the charging data may be obtained from experiments at 3 different C-rates. In embodiments, a C-rate may be a unit for measuring a speed at which a battery is charged or discharged. For example, charging (or discharging) at a C-rate of 1 C may mean that a battery is charged from 0-100% (or discharged from 100-0%) in one hour.

A2: The current, the voltage, the capacity etc., may be used as inputs to estimation techniques.

A3: The above variable may form the input to the battery model or the AI model.

A4: A non-linear minimization technique or an equivalent may be used with the above inputs to minimize the experimental error with the model predictions to estimate/train the unknown parameters.

A5: The unknown parameters may define the battery degradation dynamics, for example pre-exponential factors for Solid Electrolyte interface (SEI) and Lithium Plating (LiP) current flux, porosity decay rate, etc.

Example testing steps B1-B2 are provided below:

B1: Real time battery management system (BMS) data may be obtained or simulated.

B2: The AI model/battery model including the trained parameters may be simulated, for example using one or more of Equations 1-4 below.

$${j}_{s} ( x , t ) = - {j}_{{S}_{0}} {C}_{EC} exp [ \frac{- {α}_{c} F}{{R}_{g} T} ( {ϕ}_{1 n} - {ϕ}_{2 n} - {j}_{n} ( x , t ) {R}_{f} F ) - {U}_{SEI} ] \qquad ( Equation 1 )$$

$${j}_{l} ( x , t ) = - {j}_{{L}_{0}} exp [ \frac{- {α}_{c} F}{{R}_{g} T} ( {ϕ}_{1 n} - {ϕ}_{2 n} - {j}_{n} ( x , t ) {R}_{f} F ) ] \qquad ( Equation 2 )$$

$${ϵ}_{anode}^{cyc} = {ϵ}_{anode}^{cyc - 1} - {ϵ}_{rate} {a}_{neg} {Δ}_{film}^{cyc - 1} \qquad ( Equation 3 )$$

$${Q}_{loss}^{cyc} = {\int }_{0}^{{t}_{charg , Cyc}} ( {j}_{s} + {j}_{L} ) dt \qquad ( Equation 4 )$$

In embodiments, the user of the electronic device (100) may consider two degradation mechanisms which may lead to an abrupt capacity loss at a later stage if the battery cycling. The detailed mathematical representation of the same is provided through the Equation 1 and Equation 2. In the above equations, jₛ_{₀} may represent the pre exponential constant that is estimated/trained. This may define the rate of Solid Electrolyte Interface (SEI) current flux. Similarly j_{L}_{₀} may define the trained constant corresponding to LiP current flux which determines the rate of LiP current at different C-rates. Further, with cycling, the available pores for the reaction may decrease. Signatures corresponding to this rate of decrease in porosity may be present in the early stage of cycling, which may be estimated in the Equation 3. ∈ᵣₐₜₑ may be another trained parameter which may determine the rate of filling of pores due to the two degradation current fluxes. The current flux may determine the film thickness which in turn defines the rate of pore clogging. Equation 1 may predict the current flux due to the SEI component of degradation, while Equation 2 may define the current flux from the LiP contribution which leads to the change in intercalation current. The rate of SEI and LiP current fluxes are dependent on their corresponding potential which is the one inside the exponential. Equation 3 may be used to calculate the change in porosity of electrode as a function of film thickness. Equation 4 may define the total degradation loss at each cycle based on the j_{S}_{₀} and j_{L}_{₀} driven from Equation 1 to Equation 3.

As shown in FIG. 4B, for the testing/prediction stage (400b), the AI model or the battery model may be used to detect early indicators of such failures of the battery (150) using the trained data. Further, FIG. 4C includes a combination (400c) of a training stage 401 and a testing stage 402 for detecting early indicators of such failures of the battery (150), along with an input layer 403, an output layer 404, and trained parameters 405. In embodiments, training stage (401) may correspond to training stage (400a) described above, and testing stage (402) may correspond to testing/prediction stage (400b) described above. Example failure detection steps C1-C2 are provided below:

C1: The output layer 404 identifies remaining life of battery (150) at any point in time.

C2: The output layer 404 predicts cycle number at which sudden death would happen

FIG. 4D is an example illustration (400d) in which battery failure detection is depicted using various graphs, according to embodiments as disclosed herein. As shown in FIG. 4D, the voltage and current measurements may be obtained from the battery management system (BMS) at various initial cycle numbers. The capacity corresponding to each cycle in the training stage may be estimated using the measured variables. The dashed lines in FIG. 4D correspond to experimental data. The solid lines in FIG. 4D are for the model predictions. The mathematical model may be trained by estimating the parameters defined in the Equation 1-Equation 3 to match the model outputs, for example voltage at all times in a cycle, and capacity for each cycle with the data obtained from the BMS. The training may be performed using a maximum of, for example, the first 100 cycles, however embodiments are not limited thereto. Once a trained/parameterized model is available, the mathematical model may be used to predict the capacity/RUL at any cycle number. The AI model or the battery may be also be capable of predicting the cycle number corresponding to the sudden death of the battery (150).

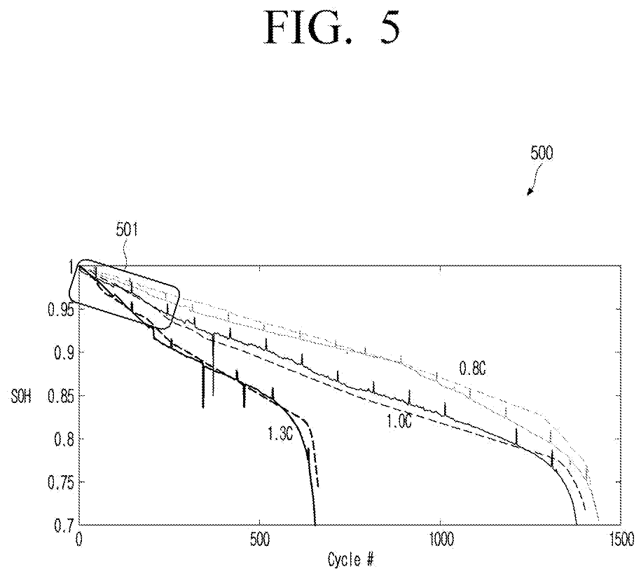

FIG. 5 is an example illustration showing a graph 500 in which comparison of battery ageing between experiments and modeling for three different C-rates using the AI model is depicted, according to embodiments as disclosed herein. FIG. 5 shows the capacity change as a function of the cycle number for three different C-rates. The dashed lines in FIG. 5 correspond to experimental data. The solid lines in FIG. 5 are for the model predicted capacity. The evaluated model capacity is matched with the BMS capacity for the first 100 cycles, which may be indicated using box 501. This portion may be referred to as the training phase, and may be the portion in which the AI model or the batter model gets parameterized. With the parameterized model, the trained mathematical model may be used to predict the capacity/RUL for any cycle number. The AI model or the battery model may be able to predict the sudden death cycle number also. FIG. 5 shows that the accuracy of capacity prediction trajectory may be within 5% for all cycles.

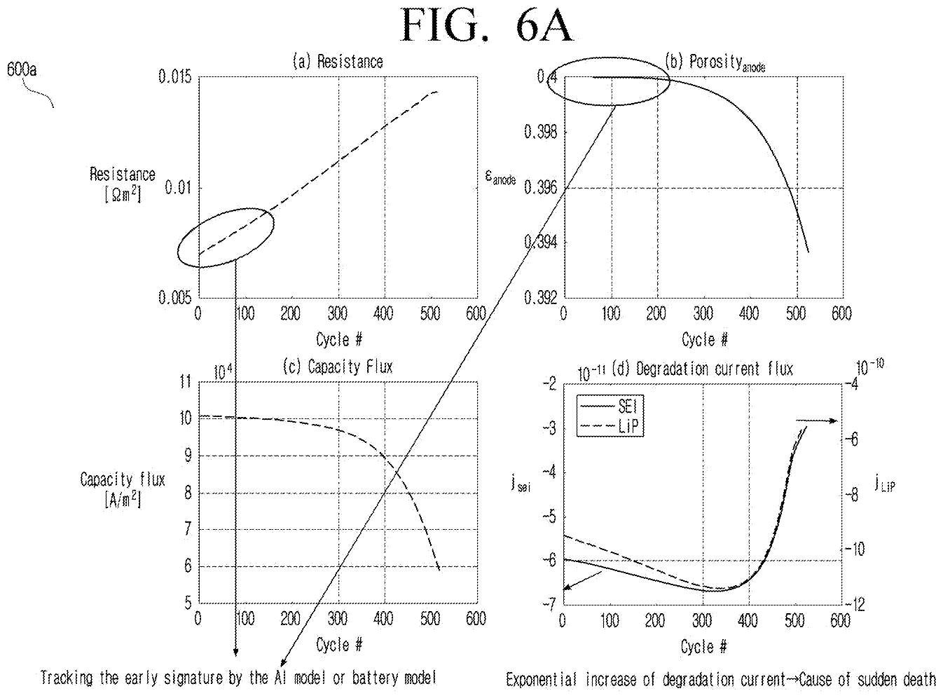

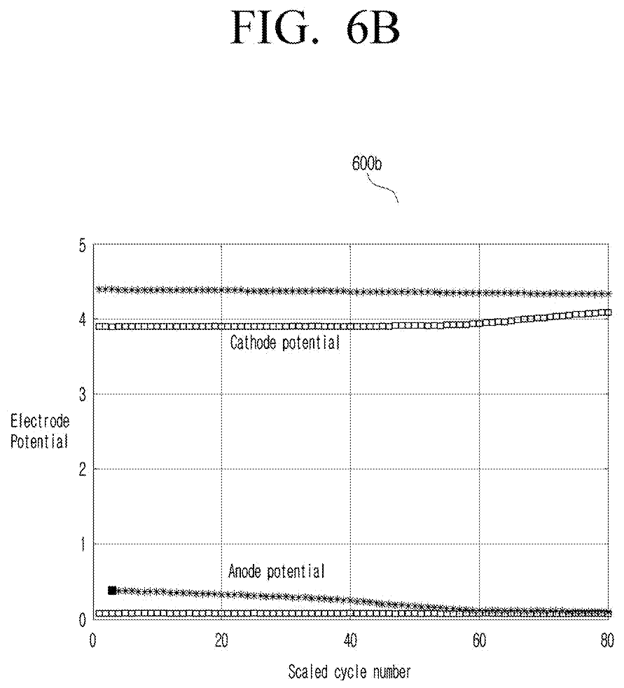

FIG. 6A and FIG. 6B are example showing graph 600a and graph 600b), in which early indicators of battery failure are depicted, according to embodiments as disclosed herein. The notation “a” of FIG. 6A indicates the resistance growth, the notation “b” of FIG. 6A indicates the porosity decay rate, the notation “c” of the FIG. 6A indicates the capacity drop, and the notation “d” of FIG. 6A indicates the pre-exponential constant that defines Lithium Plating (LiP) current flux. FIG. 6B indicates the battery parameters undergoing change before sudden death using a cathode potential and an anode potential.

The various actions, acts, blocks, steps, or the like in the processes above, for example process 200 and process 300, may be performed in the order presented, in a different order or simultaneously. Further, in some embodiments, some of the actions, acts, blocks, steps, or the like may be omitted, added, modified, skipped, or the like without departing from the scope of the invention.

The embodiments disclosed herein can be implemented through at least one software program running on at least one hardware device and performing network management functions to control the elements.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of embodiments, those skilled in the art will recognize that the embodiments herein can be practiced with modification within the spirit and scope of the embodiments as described herein.

What is claimed is:

1. An electronic device, comprising:
a memory;
a processor; and
a remaining useful life (RUL) prediction controller, coupled with the memory and the processor, and configured to:
identify at least one parameter corresponding to at least one of a physical composition and a chemical composition of a first plurality of used batteries during at least one of a charging of the first plurality of used batteries and a discharging of the first plurality of used batteries;
determine a pattern of variations in at least one of a voltage, a current, a temperature, and a resistance during every cycle of the charging of the first plurality of used batteries and every cycle of the discharging of the first plurality of used batteries until an occurrence of a failure for the first plurality of used batteries;
generate an artificial intelligence (AI) model which is trained based on a correlation between the determined pattern of variations and the at least one of the physical composition of the first plurality of used batteries and the chemical composition of the first plurality of used batteries; and
evaluate a RUL of the first plurality of used batteries using the AI model.

2. The electronic device as claimed in claim 1, wherein the RUL prediction controller is further configured to:
store the generated AI model in the memory.

3. The electronic device as claimed in claim 1, wherein the RUL prediction controller is further configured to:
identify at least one of a physical composition of a candidate battery and a chemical composition of the candidate battery, and identify a candidate pattern of variations in at least one of a voltage, a current, a temperature, and a resistance during every cycle of a charging of the candidate battery and a discharging of the candidate battery;
provide the at least one of the physical composition of the candidate battery and the chemical composition of the candidate battery, and the identified candidate pattern of variations to the AI model; and
predict an occurrence of failure of the candidate battery using the AI model.

4. The electronic device as claimed in claim 3, wherein to perform the predicting, the at RUL prediction controller is further configured to:
provide the at least one of the physical composition of the candidate battery and the chemical composition of the candidate battery, and the identified candidate pattern of variations with the AI model which is trained based on the correlation of the determined pattern of variations and the at least one of the physical composition and the chemical composition of the first plurality of used batteries; and
predict the occurrence of failure of the candidate battery based on a result obtained from the AI model.

5. The electronic device as claimed in claim 3, wherein the predicting of the occurrence of failure of the candidate battery includes at least one of determining the RUL of the candidate battery and predicting a cycle number at which a sudden death of the candidate battery will occur.

6. The electronic device as claimed in claim 1, wherein the AI model is configured to:
determine the RUL of the first plurality of used batteries based on one or more initial cycles without receiving sudden death data of the first plurality of used batteries, by identifying signs of a non-linear degradation corresponding to battery sudden death in addition to linear degradation in the one or more initial cycles to predict the battery sudden death in at a future time.

7. The electronic device as claimed in claim 1, wherein the at least one of the physical composition and the chemical composition of the first plurality of used batteries comprises a resistance growth, a porosity decay rate, a pre-exponential constant defining a Lithium Plating (LiP) current flux, a capacity drop, and a pre-exponential constant defining a solid electrolyte interface current flux.

8. The electronic device as claimed in claim 1, wherein the RUL prediction controller is further configured to track the pattern of variations in the at least one of the voltage, the current and the resistance during at least one of a charging of each of the first plurality of used batteries and a discharging of each of the first plurality of used batteries.

9. The electronic device as claimed in claim 1, wherein the RUL prediction controller is further configured to predict an occurrence of failure of a candidate battery used in at least one of an electric vehicle (EV) and a hybrid vehicle based on the AI model.

10. An electronic device, comprising:
a memory;
a processor; and
a remaining useful life (RUL) prediction controller, coupled with the memory and the processor, and configured to:
determine a charging of a battery and a discharging of the battery for a predetermined number of cycles;
measure at least one of voltage, current, a temperature, and a resistance of the battery during the charging of the battery and the discharging of the battery;
provide the at least one of the voltage, the current, the temperature, and the resistance to at least one of a battery model and an Artificial intelligence (AI) model; and
obtain at least one of a physical indicator and a chemical indicator representing a remaining useful life (RUL) of the battery using the at least one of the battery model and the AI model.

11. The electronic device as claimed in claim 10, wherein the RUL prediction controller is further configured to train the at least one of the AI model and the battery model to estimate battery parameters based on a pattern of measured voltage, current, and resistance indicative of an occurrence of failure.

12. The electronic device as claimed in claim 10, wherein the at least one of the AI model and the battery model comprises a correlation a measured pattern of variations and identified physical indicators and chemical indicators corresponding to the RUL of the battery.

13. The electronic device as claimed in claim 10, wherein the RUL prediction controller is further configured to track a pattern of variations in the at least one of the voltage, the current, the temperature, and the resistance during at least one of the charging of the battery and the discharging of the battery.

14. A method for evaluating a remaining useful life (RUL) of a battery, the method comprising:
identifying, by an electronic device, at least one parameter corresponding to at least one of a physical composition and a chemical composition of a first plurality of used batteries during at least one of a charging of the first plurality of used batteries and a discharging of the first plurality of used batteries;
determining, by the electronic device, a pattern of variations in at least one of a voltage, a current, a temperature, and a resistance during every cycle of charging of the first plurality of used batteries and every cycle of the discharging of the first plurality of used batteries until an occurrence of failure for the first plurality of used batteries;
generating, by the electronic device, an artificial intelligence (AI) model which is trained based on a correlation of the determined pattern of variations and the at least one of the physical composition of the first plurality of used batteries and the chemical composition of the first plurality of used batteries; and
evaluating, by the electronic device, a RUL of the first plurality of used batteries using the AI model.

15. The method as claimed in claim 14, further comprising storing, by the electronic device, the generated AI model in a memory.

16. An electronic device, comprising:
a memory; and
at least one processor configured to:
determine at least one physical parameter corresponding to at least one of a physical composition of a battery and a chemical composition of the battery during a predetermined number of cycles corresponding to at least one of a charging and a discharging of the battery;
determine a pattern of variations in at least one of a voltage, a current, a temperature, and a resistance of the battery during the predetermined number of cycles;
train an artificial intelligence (AI) model which based on a correlation between the determined pattern of variations and the at least one physical parameter; and
evaluate a remaining useful life (RUL) of the battery based on the AI model.

17. The electronic device of claim 16, wherein the at least one processor is further configured to:
determine a pattern of additional variations in the at least one of the voltage, the current, the temperature, and the resistance of the battery during at least one cycle after the predetermined number of cycles;
provide the pattern of additional variations to the AI model; and
evaluate an updated RUL of the battery based on the AI model.
